(19) United States
(12) Patent Application Publication
(10) Pub. No.: US 2014/0242737 A1
(43) Pub. Date: Aug. 28, 2014

(54) CATHODE DEPOSITION MASK AND METHOD OF MANUFACTURING ORGANIC LIGHT-EMITTING DISPLAY DEVICE USING THE SAME

(71) Applicant: SAMSUNG DISPLAY CO., LTD., Yongin-City (KR)

(72) Inventors: Jin Koo CHUNG, Suwon-si (KR); Kyung Ho KIM, Seoul (KR); Kwan Hyun CHO, Hwaseong-si (KR)

(73) Assignee: SAMSUNG DISPLAY CO., LTD., Yongin-City (KR)

(21) Appl. No.: 14/087,631

(22) Filed: Nov. 22, 2013

(30) Foreign Application Priority Data
Feb. 28, 2013 (KR) 10-2013-0022154

(51) Int. Cl. H01L 51/56

(52) U.S. Cl. CPC H01L 51/56
USPC 438/35; 118/504

(57) ABSTRACT

Provided is a cathode deposition mask. The cathode deposition mask includes a plurality of first columns and a plurality of second columns arranged alternately, the plurality of first columns and the plurality of second columns being parallel to each other and defining a column dimension along the length of each column, the first columns and the second columns each comprising a plurality of openings, the plurality of openings included in each first column being arranged alternately along the column dimension with respect to the openings in each adjacent first column, and the plurality of openings included in each second column being arranged alternately along the column dimension with respect to the openings in each adjacent second column.

### CLAIM OF PRIORITY

This application makes reference to, incorporates the same herein, and claims all benefits accruing under 35 U.S.C. §119 from an application for CATHODE DEPOSITION MASK AND METHOD OF MANUFACTURING ORGANIC LIGHT-EMITTING DISPLAY DEVICE USING THE SAME, earlier filed in the Korean Intellectual Property Office on Feb. 28, 2013 and there duly assigned Serial No. 10-2013-0022154.

### BACKGROUND OF THE INVENTION

1. Field of the Invention

The present invention relates to a cathode deposition mask and a method of manufacturing an organic light-emitting display device using the same, and more particularly, to a cathode deposition mask used to form a cathode divided into a plurality of separated regions and a method of manufacturing an organic light-emitting display device using the cathode deposition mask.

2. Description of the Related Art

An organic light-emitting display device includes a plurality of organic light-emitting diodes (OLEDs) and displays a desired image by controlling light emission of each of the OLEDs. An OLED may emit light at a luminance level corresponding to an electric current flowing therethrough. An OLED may include an anode, a cathode and an organic layer interposed between the anode and the cathode. Anodes included in a plurality of OLEDs may be separated from each other and may be controlled separately. Cathodes included in the OLEDs may be formed at the same time as one cathode.

A plurality of OLEDs may require different driving voltages according to the colors of light emitted from their organic layers. Therefore, in order to reduce power consumption of the OLEDs driven at relatively low voltages, different voltages may be applied to a cathode according to the colors of light emitted from the OLEDs. To apply different voltages to the cathode according to the colors of light emitted from the OLEDs, the cathode may be divided into a plurality of regions corresponding respectively to the colors of light emitted from the OLEDs. For example, the cathode may be divided into three or two separate regions.

To form a cathode divided into a plurality of regions by using one mask, a mask having island patterns separate from the other regions thereof may be used. However, the mask with the island patterns may reduce process efficiency. When the mask with the island patterns is not used, a plurality of masks may be required in order to form a cathode divided into a plurality of regions.

### SUMMARY OF THE INVENTION

Embodiments of the present invention provide a cathode deposition mask which does not have island patterns and can be used to form a cathode divided into a plurality of regions.

Embodiments of the present invention also provide a method of manufacturing an organic light-emitting display device by using one cathode deposition mask without island patterns.

However, embodiments of the present invention are not restricted to the one set forth herein. The above and other aspects of the present invention will become more apparent to one of ordinary skill in the art to which the present invention pertains by referencing the detailed description of the present invention given below.

According to an embodiment of the present invention, there is provided a cathode deposition mask comprising a plurality of first columns and a plurality of second columns arranged alternately, the plurality of first columns and the plurality of second columns being parallel to each other and defining a column dimension along the length of each column, the first columns and the second columns each comprising a plurality of openings, the plurality of openings included in each first column being arranged alternately along the column dimension with respect to the openings in each adjacent first column, and the plurality of openings included in each second column being arranged alternately along the column dimension with respect to the openings in each adjacent second column.

According to another embodiment of the present invention, there is provided a cathode deposition mask comprising a plurality of first columns, a plurality of second columns and a plurality of third columns arranged alternately, the plurality of first columns, the plurality of second columns and the plurality of third columns being parallel to each other and defining a column dimension along the length of each column, the first columns, the second columns and the third columns each comprising a plurality of openings, the plurality of openings included in each first column being arranged alternately along the column dimension with respect to the openings in each adjacent first column, the plurality of openings included in each second column being arranged alternately along the column dimension with respect to the openings in each adjacent second column, and the plurality of openings included in each third column being arranged alternately along the column dimension with respect to the openings in each adjacent third column.

According to another embodiment of the present invention, there is provided a method of manufacturing an organic light-emitting display device, the method comprising preparing a substrate comprising a plurality of pixel regions which respectively comprise anodes and organic layers disposed on the anodes, the pixel regions being arranged in a matrix comprising a series of parallel columns and a series of parallel rows, the axes of the columns defining a matrix column dimension, performing a first process of depositing a conductive material using a cathode deposition mask and performing a second process of depositing the conductive material after moving the cathode deposition mask along the matrix column dimension over a distance equal to a pitch of the pixel regions along the matrix column dimension, the cathode deposition mask comprising a plurality of first columns and a plurality of second columns arranged alternately, the plurality of first columns and the plurality of second columns being parallel to each other and defining a mask column dimension along the length of each column, a plurality of openings included in each first column being arranged alternately along the mask column dimension with respect to the openings in each adjacent first column, and a plurality of openings included in each second column being arranged alternately along the mask column dimension with respect to the openings in each adjacent second column.

According to another embodiment of the present invention, there is provided a method of manufacturing an organic light-emitting display device, the method comprising preparing a substrate comprising a plurality of pixel regions which respectively comprise anodes and organic layers disposed on the anodes, the pixels being arranged in a matrix comprising a series of parallel columns and a series of parallel rows, the axes of the columns defining a matrix column dimension, performing a first process of depositing a conductive material using a cathode deposition mask and performing a second process of depositing the conductive material after moving the cathode deposition mask along a matrix column dimension over a distance equal to a pitch of the pixel regions along the matrix column dimension, the cathode deposition mask comprising a plurality of first columns, a plurality of second columns and a plurality of third columns arranged alternately, the plurality of first columns and the plurality of second columns being parallel to each other and defining a mask column dimension along the length of each column, a plurality of openings included in each first column being arranged alternately along the mask column dimension with respect to the openings in each adjacent first column, a plurality of openings included in each second column being arranged alternately along the mask column dimension with respect to the openings in each adjacent second column, and a plurality of openings included in each third column being arranged alternately along the mask column dimension with respect to the openings in each adjacent third column.

### BRIEF DESCRIPTION OF THE DRAWINGS

A more complete appreciation of the invention and many of the attendant advantages thereof will be readily apparent as the same becomes better understood by reference to the following detailed description when considered in conjunction with the accompanying drawings in which like reference symbols indicate the same or similar components, wherein:

FIG. 1 is a flowchart illustrating a method of manufacturing an organic light-emitting display device according to an embodiment of the present invention;

FIG. 2 is a plan view of a substrate according to an embodiment of the present invention;

FIG. 3 is a cross-sectional view taken along line III-III′ of FIG. 2;

FIG. 4 is a plan view of a cathode deposition mask according to an embodiment of the present invention;

FIG. 5 is a plan view of a third opening according to an embodiment of the present invention;

FIG. 6 is a plan view of a fourth opening according to an embodiment of the present invention;

FIG. 7 is a plan view illustrating a state in which the cathode deposition mask is placed on the substrate in a first deposition process according to an embodiment of the present invention;

FIG. 8 is a plan view of the substrate after the first deposition process according to an embodiment of the present invention;

FIG. 9 is a plan view illustrating a state in which the cathode deposition mask is placed on the substrate in a second deposition process according to an embodiment of the present invention;

FIG. 10 is a plan view of the substrate after the second deposition process according to an embodiment of the present invention;

FIG. 11 is a cross-sectional view taken along line XI-XI′ of FIG. 10;

FIG. 12 is a plan view of a cathode deposition mask according to another embodiment of the present invention;

FIG. 13 is a plan view of a cathode deposition mask according to another embodiment of the present invention;

FIG. 14 is a plan view illustrating a state in which the cathode deposition mask of FIG. 13 is placed on a substrate in a first deposition process according to another embodiment of the present invention;

FIG. 15 is a plan view of the substrate after the first deposition process according to another embodiment of the present invention;

FIG. 16 is a plan view illustrating a state in which the cathode deposition mask of FIG. 13 is placed on the substrate in a second deposition process according to another embodiment of the present invention; and

FIG. 17 is a plan view of the substrate after the second deposition process according to another embodiment of the present invention.

### DETAILED DESCRIPTION OF THE INVENTION

Hereinafter, embodiments of the present invention will be described with reference to the attached drawings.

As used herein, the phrase “distance between two openings” and similar phrases refer to the shortest distance between any point on the edge of the first opening and any point on the edge of the second opening. In contrast, the phrase “a pitch of the pixel regions” and similar phrases refer to the distance between corresponding points on adjacent pixel regions within the same matrix column, such as a point on a first pixel region closest to a first column end and a point on a second pixel region closest to the first column end. The phrase “a pitch of the first columns along the row dimension” and similar phrases refer to the distance between adjacent and parallel first columns as measured along a perpendicular dimension relative to the column axes. The term “column dimension” is equivalent to “mask column dimension” as defined above unless otherwise indicated.

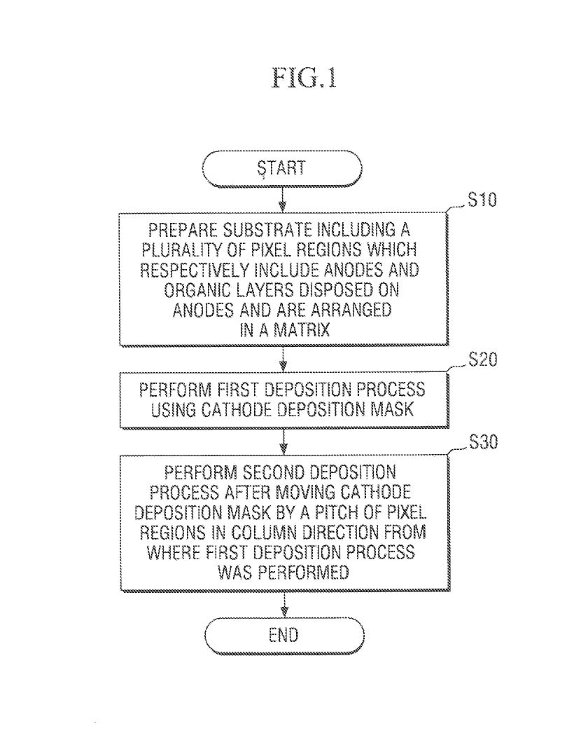

FIG. 1 is a flowchart illustrating a method of manufacturing an organic light-emitting display device according to an embodiment of the present invention. Referring to FIG. 1, the method of manufacturing an organic light-emitting display device comprises preparing a substrate including a plurality of pixel regions which respectively include anodes and organic layers disposed on the anodes, the pixel regions being arranged in a matrix comprising a series of parallel columns and a series of parallel rows, the axes of the columns defining a matrix column dimension (operation S10), performing a first deposition process using a cathode deposition mask (operation S20), and performing a second deposition process after moving the cathode deposition mask along the matrix column dimension over a distance equal to a pitch of the pixel regions along the matrix column dimension (operation S30).

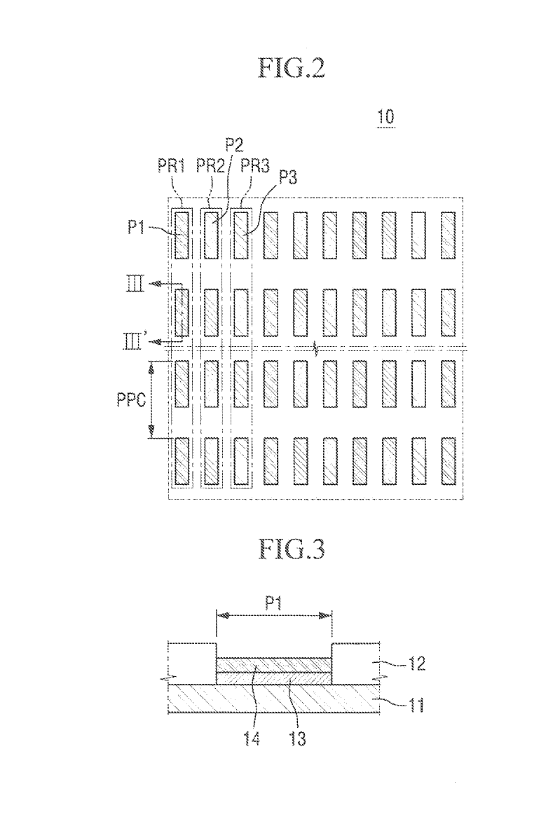

A substrate prepared in the preparing of the substrate including the pixel regions which respectively include the anodes and the organic layers disposed on the anodes and are arranged in a matrix (operation S10) will now be described with reference to FIG. 2. FIG. 2 is a plan view of a substrate 10 according to an embodiment of the present invention.

Referring to FIG. 2, the substrate 10 includes a plurality of pixel regions (P1 through P3) arranged in a matrix. The pixel regions (P1 through P3) may be arranged at a pixel pitch PPC along the column direction. The pixel regions (P1 through P3) may include first pixel regions P1, second pixel regions P2, and third pixel regions P3. The first through third pixel regions P1 through P3 may include organic layers which emit light of different colors. For example, each of the first pixel regions P1 may include an organic layer which may emit red light, each of the second pixel regions P2 may include an organic layer which may emit green light, and each of the third pixel regions P3 may include an organic layer which may emit blue light. However, this is merely an example, and the colors of light emitted from the organic layers included in the first through third pixel regions P1 through P3 may vary depending on embodiments.

The first through third pixel regions P1 through P3 may include first through third pixel region columns PR1 through PR3. The first through third pixel region columns PR1 through PR3 may be arranged alternately along a row dimension that is perpendicular to the column dimension. Each of the first pixel region columns PR1 may include a plurality of first pixel regions PR1. The first pixel region columns PR1 may not include pixel regions other than the first pixel regions PR1. Each of the second pixel region columns PR2 may include a plurality of second pixel regions PR2. The second pixel region columns PR2 may not include pixel regions other than the second pixel region PR2. Each of the third pixel region columns PR3 may include a plurality of third pixel regions PR3. The third pixel region columns PR3 may not include pixel regions other than the third pixel regions PR3.

The substrate 10 will now be described in greater detail with reference to FIG. 3. FIG. 3 is a cross-sectional view taken along line III-III′ of FIG. 2.

Referring to FIG. 3, the substrate 10 may include a base substrate 11, a pixel defining layer 12, an anode 13, and an organic layer 14. The anode 13 and the organic layer 14 may be included in a first pixel region P1.

The base substrate 11 may support other elements of the substrate 10. The base substrate 11 may be formed of an insulating material. The base substrate 11 may be formed of, but not limited to, synthetic resin, glass, or silicon. The base substrate 11 may be formed of a transparent material or an opaque material. In a bottom emission type organic light-emitting display device, the base substrate 11 may be formed of a transparent material.

Although not shown in the drawing, the base substrate 11 may include a thin-film transistor (TFT). The TFT may be connected to the anode 13. The TFT may control light emission of the organic layer 14 by controlling a voltage or current applied to the anode 13.

The pixel defining layer 12 may be disposed on the base substrate 11. The pixel defining layer 12 may be formed of an insulating material. The first through third pixel regions P1 through P3 may be defined by regions in which the pixel defining layer 12 is not disposed.

The anode 13 may be disposed on the base substrate 11. The anode 13 may be disposed in the first pixel region P1. The anode 13 may be formed of a conductive material. In a top emission type organic light-emitting display device, the anode 13 may be formed of a material that reflects light. In the top emission type organic light-emitting display device, the anode 13 may be formed of, but not limited to, lithium (Li), calcium (Ca), lithium fluoride/calcium (LiF/Ca), lithium fluoride/aluminum (LiF/Al), aluminum (Al), silver (Ag), magnesium (Mg), or gold (Au). In a bottom emission type organic light-emitting display device, the anode 13 may be formed of an optically transparent material. In the bottom emission organic light-emitting display device, the anode 13 may be formed of, but not limited to, a co-deposition material including one or more of indium tin oxide (ITO), indium zinc oxide (IZO), zinc oxide (ZnO), indium oxide (In₂O₃), Mg and Ag, or may be formed of Mg, Ag, Ca, Li or Al.

The organic layer 14 may be disposed on the anode 12. The organic layer 14 may be included in the first pixel region P1. The organic layer 14 may emit light in response to an electric current flowing therethrough. More specifically, holes and electrons provided to the organic layer 14 may combine to form excitons. When an energy level of the excitons is changed from an excited state to a ground state, the organic layer 14 may emit light. The organic layer 14 may emit light of one of, but not limited to, red, green and blue colors. The brightness of light emitted from the organic layer 14 may correspond to the size of an electric current flowing through the organic layer 14.

While the cross-section of the substrate 10 in the first pixel region P1 only has been described above with reference to FIG. 3, descriptions of the cross-section of the substrate 10 in the second and third pixel regions P2 and P3 may be substantially identical to the description of the cross-section of the substrate 10 in the first pixel region P1.

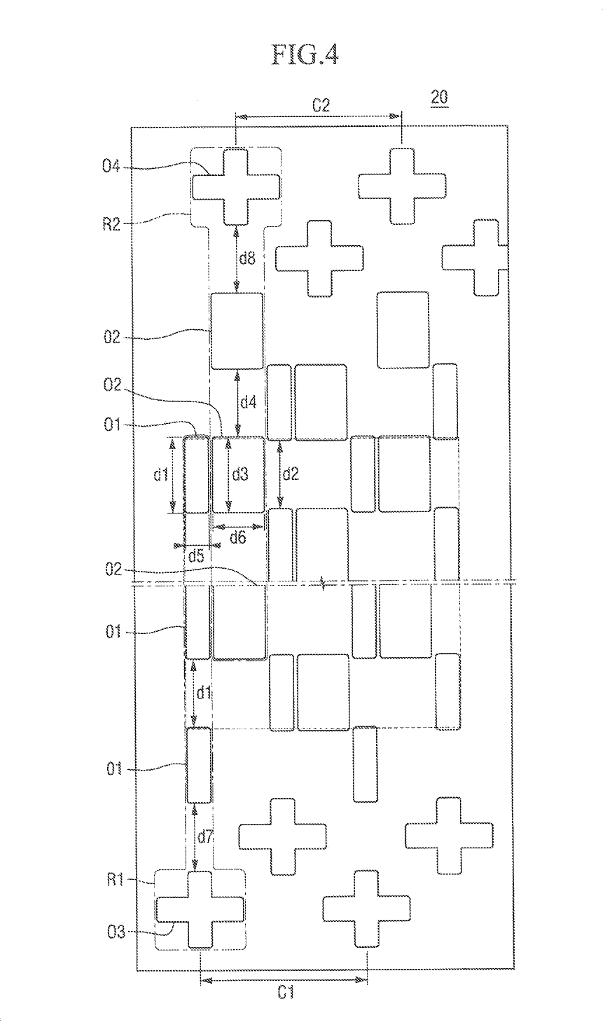

A cathode deposition mask used in the performing of the first deposition process using the cathode deposition mask (operation S20) will be described below with reference to FIG. 4. FIG. 4 is a plan view of a cathode deposition mask 20 according to an embodiment of the present invention.

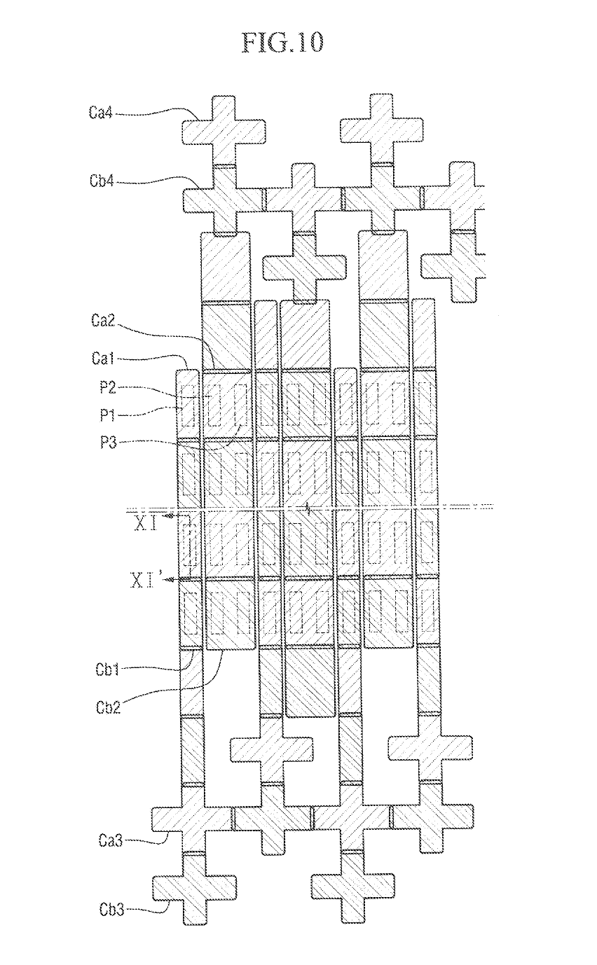

In certain embodiments, if the various openings in the cathode deposition mask are formed with appropriate dimensions, the second deposition process will form one continuous cathode corresponding to the first columns of the mask (pixels P1) and another continuous cathode corresponding to the second columns of the mask (pixels P2 and P3). The overall result of this scheme is illustrated in FIG. 10.

Referring to FIG. 4, the cathode deposition mask 20 includes a plurality of openings (O1 through O4). The openings (O1 through O4) include a plurality of first columns R1 and a plurality of second columns R2. The first columns R1 and the second columns R2 may be arranged alternately, the first columns and the second columns being parallel to each other and defining a column dimension along the length of each column. In certain embodiments, the first columns and the second columns may be arranged in the same plane, with a row dimension being defined as perpendicular to the column dimension and within the plane including the first columns and the second columns. A plurality of openings (O1, O3) included in each first column R1 may be arranged alternately along the column dimension with respect to the openings in each adjacent first column. A plurality of openings (O2, 04) included in each second column R2 may be arranged alternately along the column dimension with respect to the openings in each adjacent second column.

Each of the first columns R1 may include a plurality of first openings O1 and a third opening O3. The number of the third openings O3 included in each of the first columns R1 may be one. The third opening O3 may be disposed adjacent to an end of each of the first columns R1. A length d1 of the first openings O1 along the column dimension may be greater than a distance d2 between two first openings O1 which are adjacent to each other along the column dimension. If the length d1 of the first openings O1 along the column dimension is greater than the distance d2 between the two first openings O1 which are adjacent to each other along the column dimension, cathode patterns formed in the first deposition process through the first openings O1 arranged along the column dimension may be connected with cathode patterns formed in the second deposition process through the first openings O1. The length d1 of the first openings O1 along the column dimension may be greater than a distance d7 between the third opening O3 and a first opening O1 which is adjacent to the third opening O3 along the column dimension. If the length d1 of the first openings O1 along the column dimension is greater than the distance d7 between the third opening O3 and the first opening O1 which is adjacent to the third opening O3 along the column dimension, cathode patterns formed in the first deposition process through the third opening O3 and the first opening O1 which is adjacent to the third opening O3 along the column dimension may be connected by a cathode pattern formed in the second deposition process through the first opening O1 which is adjacent to the third opening O3 along the column dimension. The first openings O1 included in each of the first columns R1 may partially overlap, along the column dimension, the first openings O1 included in another first column R1 which is adjacent to the first column R1. If the first openings O1 included in each of the first columns R1 partially overlap, along the column dimension, the first openings O1 included in another first column R1 which is adjacent to the first column R1, cathode patterns formed in the first deposition process through the first openings O1 arranged along the column dimension may be connected by cathode patterns formed in the second deposition process through the first openings O1.

The third opening O3 will now be described in greater detail with reference to FIG. 5. FIG. 5 is a plan view of the third opening O3 according to an embodiment of the present invention.

Referring to FIG. 5, a length d9 of the third opening O3 along the row dimension may be greater than a pitch C1 of the first columns R1 along the row dimension shown in FIG. 4. If the length d9 of the third opening O3 along the row dimension is greater than the pitch C1 of the first columns R1 along the row dimension, cathode patterns that are formed in the first deposition process through the first openings O1 and the third opening O3 included in each of the first columns R1 and are adjacent along the row dimension may be connected by a cathode pattern formed in the second deposition process through the third opening O3.

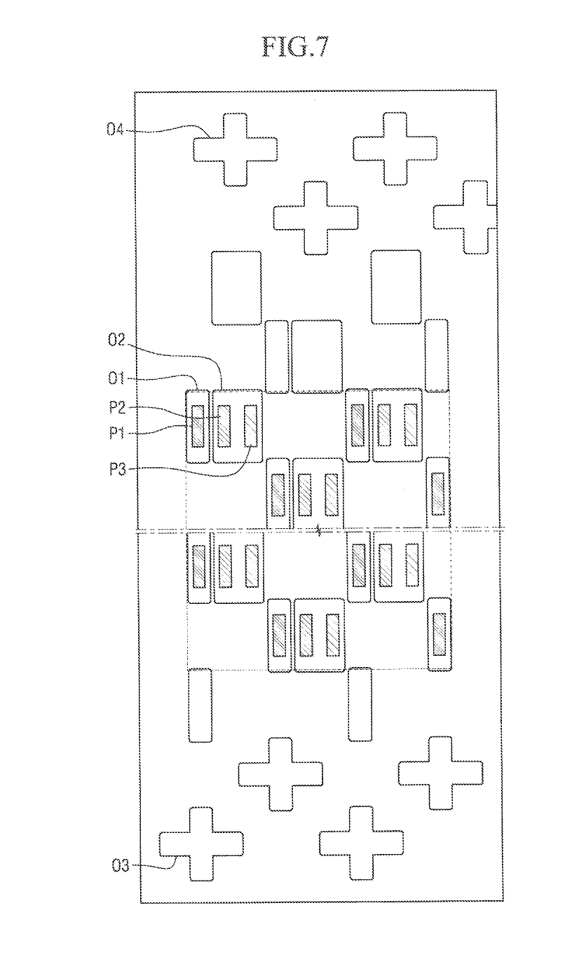

A length d10 of the third opening O3 along the column dimension may be greater than the distance d7 between the third opening O3 and a first opening O1 which is adjacent to the third opening O3 along the column dimension. In FIGS. 7 and 9 to be described later, for the second deposition process, the cathode deposition mask 20 is moved downward by the pixel pitch PPC from its original position, where the first deposition process was performed. However, according to some embodiments, the position of the cathode deposition mask 20 in the first deposition process and the position of the cathode deposition mask 20 in the second deposition process can be reversed. That is, for the second deposition process, the cathode deposition mask 20 can be moved upward by the pixel pitch PPC from its initial position, where the first deposition process was performed. In this case, if the length d10 of the third opening O3 along the column dimension is greater than the distance d7 between the third opening O3 and the first opening O1 which is adjacent to the third opening O3 along the column dimension, cathode patterns formed in the first deposition process through the third opening O3 and the first opening O1 which is adjacent to the third opening O3 along the column dimension may be connected by a cathode pattern formed in the second deposition process through the third opening O3.

The third opening O3 may include a first region A1 and a second region A2. In the first region A1, a length of the third opening O3 along the column dimension may be greater than a width of region A1 along the row dimension. In the second region A2, a length of the third opening O3 along the row dimension may be greater than a width of region A2 along the column dimension. A width d11 of the second region A2 of the third opening O3 along the column dimension may be smaller than the distance d7 between the third opening O3 and the first opening O1 which is adjacent to the third opening O3 along the column dimension. A width d12 of the first region A1 of the third opening O3 along the row dimension may be equal to or less than a width d5 of the first openings O1 along the row dimension.

Referring back to FIG. 4, each of the second columns R2 may include a plurality of second openings O2 and a fourth opening 04. The number of the second openings O2 included in one second column R2 may be equal to the number of the first openings O1 included in one first column R1. The number of the fourth openings 04 included in each of the second columns R2 may be one. In certain embodiments, each first column and each second column may have a first end and a second end, the first end of each first column being adjacent to the first end of each adjacent second column, the second end of each second column being adjacent to the second end of each adjacent first column. The fourth opening 04 may be disposed adjacent to the second end of each of the second columns R2. The third opening O3 may be disposed adjacent to the first end of each of the first columns R1.

A length d3 of the second openings O2 along the column dimension may be greater than a distance d4 between two second openings O2 which are adjacent to each other along the column dimension. If the length d3 of the second openings O2 along the column dimension is greater than the distance d4 between two second openings O2 which are adjacent to each other along the column dimension, cathode patterns that are formed in the first deposition process through the second openings O2 and are arranged along the column dimension may be connected by cathode patterns formed in the second deposition process through the second openings O2. The length d3 of the second openings O2 along the column dimension may be greater than a distance d8 between the fourth opening O4 and a second opening O2 which is adjacent to the fourth opening O4 along the column dimension. If the length d3 of the second openings O2 along the column dimension is greater than the distance d8 between the fourth opening O4 and the second opening O2 which is adjacent to the fourth opening O4 along the column dimension, cathode patterns formed in the first deposition process through the fourth opening O4 and the second opening O2 which is adjacent to the fourth opening O4 along the column dimension may be connected by a cathode pattern formed in the second deposition process through the second opening O2 which is adjacent to the fourth opening O4 along the column dimension.

The second openings O2 included in each of the second columns R2 may partially overlap, along the column dimension, the second openings O2 included in another second column R2 which is adjacent to the second column R2 along the row dimension. If the second openings O2 included in each of the second columns R2 partially overlap, along the column dimension, the second openings O2 included in another second column R2 which is adjacent to the second column R2 along the row dimension, cathode patterns formed in the first deposition process through the second openings O2 arranged along the column dimension may be connected by cathode patterns formed in the second deposition process through the second openings O2.

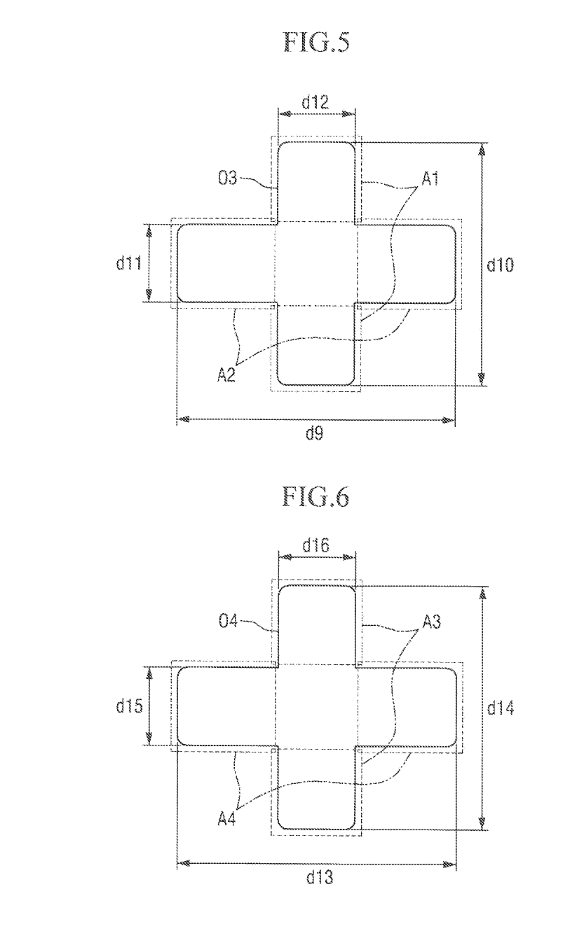

The fourth opening O4 will now be described in greater detail with reference to FIG. 6. FIG. 6 is a plan view of the fourth opening O4 according to an embodiment of the present invention.

Referring to FIG. 6, a length d13 of the fourth opening O4 in the row direction may be greater than a pitch C2 of the second columns R2 along the row dimension in FIG. 4. If the length d13 of the fourth opening O4 along the row dimension is greater than the pitch C2 of the second columns R2 along the row dimension, adjacent cathode patterns formed in the first deposition process through the second openings O2 and the fourth opening O4 included in each of the second columns R2 may be connected by a cathode pattern formed in the second deposition process through the fourth opening O4.

A length d14 of the fourth opening O4 along the column dimension may be greater than the distance d8 between the fourth opening O4 and a second opening O2 which is adjacent to the fourth opening O4 along the column dimension. If the length d14 of the fourth opening O4 along the column dimension is greater than the distance d8 between the fourth opening O4 and the second opening O2 which is adjacent to the fourth opening O4 along the column dimension, cathode patterns formed in the first deposition process through the fourth opening O4 and the second opening O2 which is adjacent to the fourth opening O4 along the column dimension may be connected by a cathode pattern formed in the second deposition process through the fourth opening O4.

The fourth opening O4 may include a third region A3 and a fourth region A4. In the third region A3, a length of the fourth opening O4 along the column dimension may be greater than a width of region A3 along the row dimension. In the fourth region A4, a length of the fourth opening O4 along the row dimension may be greater than a width of region A4 along the column dimension. A width d15 of the fourth region A4 of the fourth opening O4 along the column dimension may be smaller than the distance d8 between the fourth opening O4 and the second opening O2 which is adjacent to the fourth opening O4 along the column dimension. A width d16 of the third region A3 of the fourth opening O4 along the row dimension may be equal to or less than a width d6 of the second openings O2 along the row dimension.

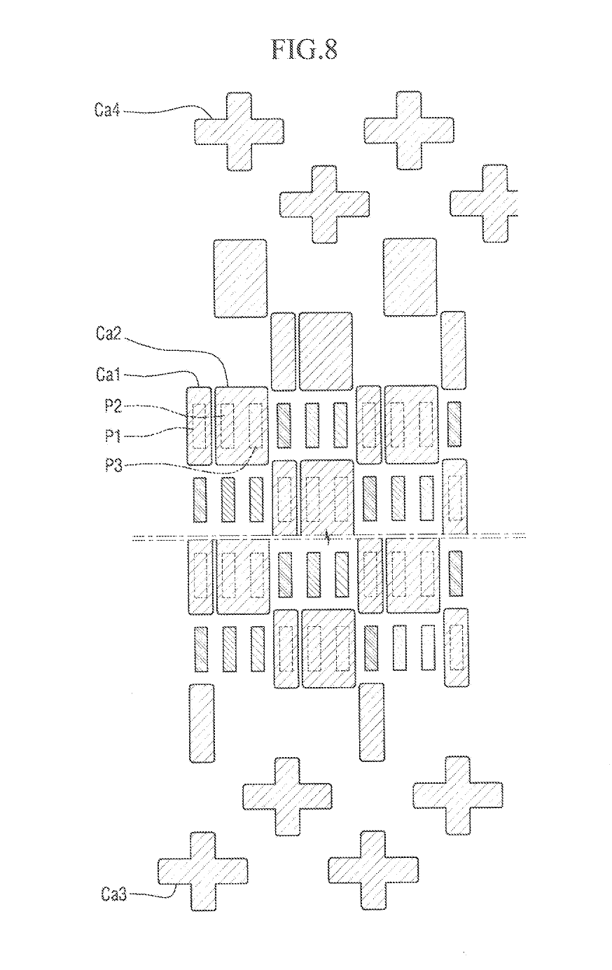

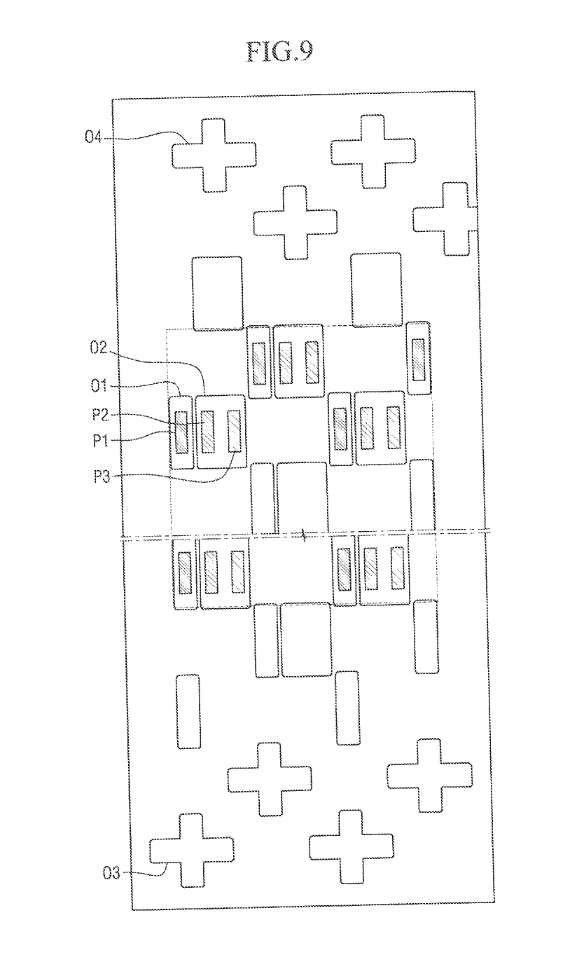

The performing of the first deposition process using the cathode deposition mask (operation S20) will now be described with reference to FIGS. 7 and 8. FIG. 7 is a plan view illustrating a state in which the cathode deposition mask 20 is placed on the substrate 10 in the first deposition process according to an embodiment of the present invention. FIG. 8 is a plan view of the substrate 10 after the first deposition process according to an embodiment of the present invention.

Referring to FIG. 7, the performing of the first deposition process using the cathode deposition mask (operation S20) includes placing the cathode deposition mask 20 on the substrate 10 as shown in FIG. 7. In the first deposition process, the first columns R1 may be placed on the first pixel region columns PR1, and the second columns R2 may be placed on the second pixel region columns PR2 and the third pixel region columns PR3.

In the first deposition process, the first pixel regions P1 may be exposed through the first openings O1 of the cathode deposition mask 20. One first opening O1 of the cathode deposition mask 20 may expose one first pixel region P1. In certain embodiments, first openings O1 of the cathode deposition mask 20 each expose no more than one first pixel region P1 in the first deposition step, and the mask pattern shown in the embodiment of FIG. 7 ensures that the second deposition step will not add more cathode material to the same first pixel regions P1 that were exposed in the first deposition step. The deterioration of display quality of an organic light-emitting display device that might result from nonuniform cathode structures and the corresponding variation in index of refraction of the pixel cathode layers may thereby be prevented.

In certain embodiments, the cathode deposition mask may be designed to be useful for exposing substrates having a varied number of pixel regions in each of the first columns and the second columns. At least one of a plurality of first openings O1 included in one first column R1 of the cathode deposition mask may overlay a region of the substrate that does not include a first pixel region P1. The number of first openings O1 included in one first column R1 of the cathode deposition mask may be greater than half the number of the first pixel regions P1 included in one first pixel region column PR1 on the substrate.

In the first deposition process, the second and third pixel regions P2 and P3 may be exposed through the second openings O2 of the cathode deposition mask 20. One second opening O2 of the cathode deposition mask 20 may expose one second pixel region P2 and one third pixel region P3. In certain embodiments, one second opening O2 of the cathode deposition mask 20 exposes no more than one second pixel region P2 and one third pixel region P3 in the first deposition step, and the mask pattern shown in the embodiment of FIG. 7 ensures that the second deposition step will not add more cathode material to the same first pixel regions P2 and P3 that were exposed in the first deposition step. The deterioration of display quality of the organic light-emitting display device that might result from nonuniform cathode structures and the corresponding variation in index of refraction of the pixel cathode layers may thereby be prevented.

Again, with respect to pixel columns PR2 and PR3 on the substrate, which are overlaid by the second columns of the cathode deposition mask, the cathode deposition mask may be designed for exposing substrates having a varied number of pixel regions. At least one of a plurality of second openings O2 included in one second column R2 of the cathode deposition mask may overlay a region of the substrate that does not include a second pixel region P2 and a third pixel region P3. The number of the second openings O2 included in one second column R2 may be greater than half the number of the second pixel regions P2 included in one second pixel region column PR2 and half the number of the third pixel regions P3 included in one third pixel region column PR3.

Referring to FIG. 8, first through fourth step S20 cathode patterns Ca1 through Ca4 may be formed on the substrate 10 by the first deposition process as described above. The first through fourth step S20 cathode patterns Ca1 through Ca4 may be formed of a conductive material. In a top emission type organic light-emitting display device, the first through fourth step S20 cathode patterns Ca1 through Ca4 may be formed of a transparent material. In the top emission type organic light-emitting display device, the first through fourth step S20 cathode patterns Ca1 through Ca4 may be formed of, but are not limited to, a co-deposition material including one or more of indium tin oxide (ITO), indium zinc oxide (IZO), ZnO, In₂O₃, Mg and Ag. First through fourth cathode patterns Ca1 through Ca4 may also be formed of one of Mg, Ag, Ca, Li and Al. In a bottom emission type organic light-emitting display device, the first through fourth step S20 cathode patterns Ca1 through Ca4 may be formed of a material that reflects light. In the bottom emission type organic light-emitting display device, the first through fourth step S20 cathode patterns Ca1 through Ca4 may be formed of, but are not limited to, one of Li, Ca, LiF/Ca, LiF/Al, Al, Ag, Mg and Au.

The first through fourth step S20 cathode patterns Ca1 through Ca4 may be cathode patterns deposited on the substrate 10 through the first through fourth openings, O1 through O4, respectively. Positions and shapes of the first through fourth step S20 cathode patterns Ca1 through Ca4 may be substantially identical to those of the first through fourth openings O1 through O4 shown in FIG. 7, respectively.

The performing of the second deposition process after moving the cathode deposition mask a distance equal to the pitch of the pixel regions along the column dimension from the position where the first deposition process was performed (operation S30) will now be described with reference to FIGS. 9 and 10. FIG. 9 is a plan view illustrating a state in which the cathode deposition mask 20 is placed on the substrate 10 in the second deposition process according to an embodiment of the present invention. FIG. 10 is a plan view of the substrate 10 after the second deposition process according to an embodiment of the present invention.

Referring to FIG. 9, the performing of the second deposition process using the cathode deposition mask (operation S30) includes placing the cathode deposition mask 20 on the substrate 10 as shown in FIG. 9. For the second deposition process, the cathode deposition mask 20 may be moved a distance equal to the pixel pitch PPC of a plurality of pixel regions along the column dimension from the position where the first deposition process was performed. To be placed as shown in FIG. 9, the cathode deposition mask 20 may be moved downward in the column direction a distance equal to the pixel pitch PPC of the pixel regions along the column dimension from the position of the cathode deposition mask 20 in FIG. 7. However, this is merely an example. According to some embodiments, the position of the cathode deposition mask 20 in the first deposition process shown in FIG. 7 and the position of the cathode deposition mask 20 in the second deposition process shown in FIG. 9 can be reversed.

In the second deposition process, after adjustment of the position of the cathode deposition mask by a distance equal to the pixel pitch PPC along the column dimension, the first columns R1 may again be placed on the first pixel region columns PR1, and the second columns R2 may again be placed on the second pixel region columns PR2 and the third pixel region columns PR3.

In the second deposition process, the first pixel regions P1 may be exposed through the first openings O1 of the cathode deposition mask 20. One first opening O1 of the cathode deposition mask 20 may expose one first pixel region P1. If one first opening O1 of the cathode deposition mask 20 exposes one first pixel region P1, the second deposition process will not deposit cathode material over the same positions of the first pixel region P1 where cathode material was deposited by the first deposition process. Deterioration of display quality of the organic light-emitting display device may be prevented when cathode materials are deposited in one operation in a uniform and homogeneous manner on each individual pixel and variation in the index of refraction of the cathode layers of the pixel regions may be minimized. At least one of a plurality of first openings O1 included in one first column R1 of the cathode deposition mask may overlay a region of the substrate that does not include a first pixel region P1. This allows for use of the cathode deposition mask on substrates prepared with varied numbers of pixel regions P1. According to some embodiments, in the second deposition process, the second and third pixel regions P2 and P3 may be exposed through the second openings O2 of the cathode deposition mask 20. One second opening O2 of the cathode deposition mask 20 may expose one second pixel region P2 and one third pixel region P3. If one second opening O2 of the cathode deposition mask 20 exposes one second pixel region P2 and one third pixel region P3, the second deposition process will not deposit cathode material over the same positions of the second pixel region P2 and the third pixel region P3 where cathode material was deposited by the first deposition process. Deterioration of display quality of the organic light-emitting display device may be prevented when cathode materials are deposited in one operation in a uniform and homogeneous manner on each individual pixel and variation in the index of refraction of the cathode layers of the pixel regions may be minimized. At least one of a plurality of second openings O2 included in one second column R2 of the cathode deposition mask may overlay a region of the substrate that does not include second pixel region P2 and a third pixel region P3.

Referring to FIG. 10, first through fourth step S30 cathode patterns Cb1 through Cb4 may be formed on the substrate 10 by the second deposition process. The first through fourth step S30 cathode patterns Cb1 through Cb4 may be formed of substantially the same material as the first through fourth step S20 cathode patterns Ca1 through Ca4 that were formed in the first deposition process. The first through fourth step S30 cathode patterns Cb1 through Cb4 may be cathode patterns deposited on the substrate 10 through the first through fourth openings O1 through O4, respectively.

Each of the first step S30 cathode patterns Cb1 may be formed to partially overlap a first step S20 cathode pattern Ca1 or a third step S20 cathode pattern Ca3 which is adjacent to the first step S30 cathode pattern Cb1 along the column dimension. Each of the third step S30 cathode patterns Cb3 may be formed to overlap third step S20 cathode patterns Ca3, in particular, a third step S20 cathode pattern Ca3 which is adjacent to the third step S30 cathode pattern Cb3 along the column dimension and a third step S20 cathode pattern Ca3 which is adjacent to the third step S30 cathode pattern Cb3 along the row dimension. In this way, the first step S20 cathode patterns Ca1, the third step S20 cathode patterns Ca3, the first step S30 cathode patterns Cb1, and the third step S30 cathode patterns Cb3 disposed on the substrate 10 may all be connected to form a first cathode. The first cathode may be disposed on the first pixel regions P1 so that the cathodes of all first pixel regions P1 are interconnected.

Each of the second step S30 cathode patterns Cb2 may be formed to partially overlap a second step S20 cathode pattern Ca2 or a fourth step S20 cathode pattern Ca4 which is adjacent to the second step S30 cathode pattern Cb2 along the column dimension. Each of the fourth step S30 cathode patterns Cb4 may be formed to overlap a second step S20 cathode pattern Ca2 which is adjacent to the fourth step S30 cathode pattern Cb4 along the column dimension or a fourth step S20 cathode pattern Ca4 and a fourth step S20 cathode pattern Ca4 which is adjacent to the fourth step S30 cathode pattern Cb4 along the row dimension. In this way, the second step S20 cathode patterns Ca2, the fourth step S20 cathode patterns Ca4, the second step S30 cathode patterns Cb2, and the fourth step S30 cathode patterns Cb4 disposed on the substrate 10 may all be connected to form a second cathode. The second cathode may be disposed on the second and third pixel regions P2 and P3. The second cathode may be separated from the first cathode.

As described above, according to one embodiment of the present invention, an organic light-emitting display device including first and second cathodes which are separated from each other can be formed using one cathode deposition mask 20 without island patterns. The number of masks needed to deposit cathodes can be reduced, thereby simplifying the manufacturing process. In addition, since different voltages can be applied to the cathodes according to the colors of pixels, power consumption of the organic light-emitting display device can be reduced.

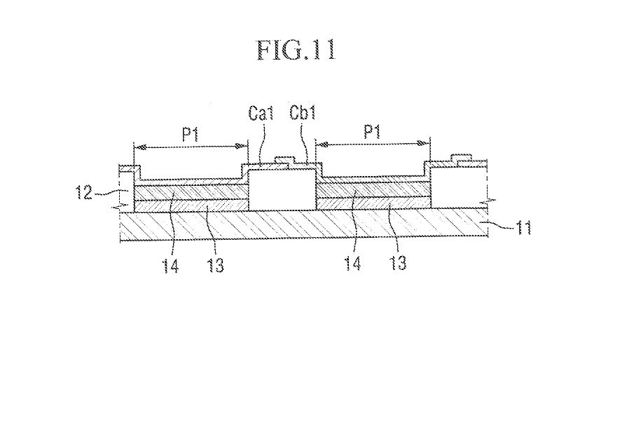

An overlap region between a first step S20 cathode pattern Ca1 and a first step S30 cathode pattern Cb1 will now be described in greater detail with reference to FIG. 11. FIG. 11 is a cross-sectional view taken along line XI-XI′ of FIG. 10.

Referring to FIG. 11, an overlap region between a first step S20 cathode pattern Ca1 and a first step S30 cathode pattern Cb1 may be formed on the pixel defining layer 12. Importantly, according to certain embodiments, no overlap region between the first step S20 cathode pattern Ca1 and the first step S30 cathode pattern Cb1 is formed on the first pixel regions P1. In a top emission type organic light-emitting display device, if there is no overlap region between the first step S20 cathode pattern Ca1 and the first step S30 cathode pattern Cb1 on the first pixel regions P1, a change in the refractive index of a cathode disposed on a path of light emitted from the organic layer 14 can be reduced, thereby preventing deterioration of display quality of the organic light-emitting display device.

While the overlap region between the first step S20 cathode pattern Ca1 and the first step S30 cathode pattern Cb1 has been described above with reference to FIG. 11, a description of an overlap region between a second step S20 cathode pattern Ca2 and a second step S30 cathode pattern Cb2 may be substantially identical to the description of the overlap region between the first step S20 cathode pattern Ca1 and the first step S30 cathode pattern Cb1.

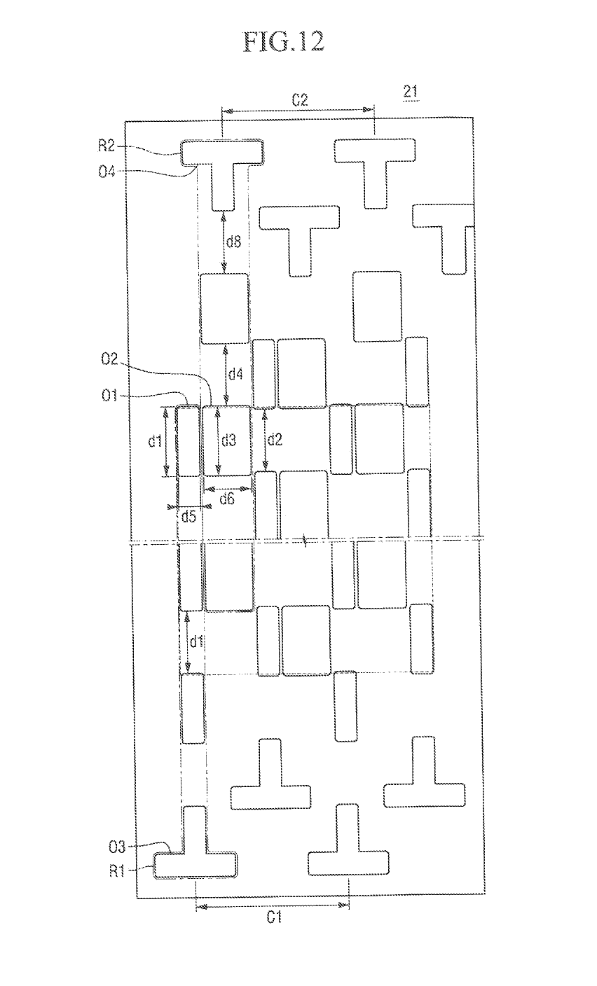

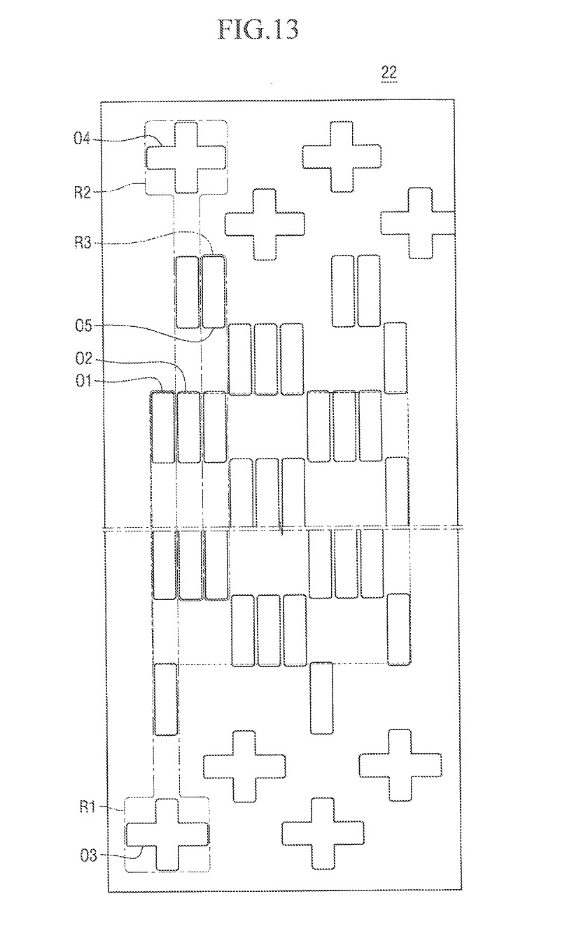

Another embodiment of the present invention will now be described with reference to FIG. 12. FIG. 12 is a plan view of a cathode deposition mask 21 according to another embodiment of the present invention.

Referring to FIG. 12, third and fourth openings O3 and O4 in the cathode deposition mask 21 may have different shapes from the third and fourth openings O3 and O4 in the cathode deposition mask 20 of FIG. 4. While the third and fourth openings O3 and O4 in the cathode deposition mask 20 of FIG. 4 are ‘+’-shaped, the third openings O3 in the cathode deposition mask 21 of FIG. 12 may be ‘⊥’-shaped, and the fourth openings O4 in the cathode deposition mask 21 of FIG. 12 may be ‘T’-shaped. Other features of the cathode deposition mask 21 are substantially identical to those of the cathode deposition mask 20 described above with reference to FIG. 4, and thus a description thereof will be omitted. A method of manufacturing an organic light-emitting display device using the cathode deposition mask 21 is substantially identical to the method of manufacturing an organic light-emitting display device using the cathode deposition mask 20 described above with reference to FIGS. 1 through 11, and thus a description thereof will be omitted.

The shapes of the third and fourth openings O3 and O4 shown in FIG. 12 are merely an example and can vary depending on embodiments.

Another embodiment of the present invention will now be described with reference to FIGS. 13 through 17. FIG. 13 is a plan view of a cathode deposition mask 22 according to another embodiment of the present invention. The terms “column dimension” and “row dimension” are defined in a manner analogous to that described above.

Referring to FIG. 13, the cathode deposition mask 22 includes a plurality of openings (O1 through O5). The openings (O1 through O5) are disposed in a plurality of first columns R1, a plurality of second columns R2, and a plurality of third columns R3. The first columns R1, the second columns R2, and the third columns R3 are arranged in parallel and alternately along a row dimension. A plurality of openings (O1, O3) included in each first column R1 are arranged alternately along the column dimension with respect to the openings in each adjacent first column. A plurality of openings (O2, O4) included in each second column R2 are arranged alternately along the column dimension with respect to the openings in each adjacent second column. A plurality of openings (O5) included in each third column R3 are arranged alternately along the column dimension with respect to the openings in each adjacent third column.

Each of the first columns R1 may include a plurality of first openings O1 and a third opening O3. The first openings O1 and the third opening O3 included in each of the first columns R1 are substantially identical to the first openings O1 and the third opening O3 included in each of the first columns R1 of FIG. 4, and thus a description thereof will be omitted.

Each of the second columns R2 may include a plurality of second openings O2 and a fourth opening O4. The second openings O2 and the fourth opening O4 included in each of the second columns R2 are substantially identical to the second openings O2 and the fourth opening O4 included in each of the second columns R2 of FIG. 4, and thus a description thereof will be omitted.

Each of the third columns R3 may include a plurality of fifth openings O5. The number of the fifth openings O5 included in one third column R3 may be equal to the number of the first openings O1 included in one first column R1 or the number of the second openings O2 included in one second column R2. A length of the fifth openings O5 along the column dimension may be greater than a distance between two fifth openings O5 which are adjacent to each other along the column dimension. If the length of the fifth openings O5 along the column dimension is greater than the distance between the two fifth openings O5 which are adjacent to each other along the column dimension, cathode patterns formed in a first deposition process through the fifth openings O5 arranged along the column dimension may be connected by cathode patterns formed in a second deposition process through the fifth openings O5. The fifth openings O5 included in each of the third columns R3 may partially overlap, along the column dimension, the fifth openings O5 included in another third column R3 which is adjacent to the third column R3 along the row dimension. If the fifth openings O5 included in each of the third columns R3 partially overlap, along the column dimension, the fifth openings O5 included in another third column R3 which is adjacent to the third column R3 along the row dimension, cathode patterns formed in the first deposition process through the fifth openings O5 arranged along the column dimension may be connected by cathode patterns formed in the second deposition process through the fifth openings O1.

A flowchart illustrating a method of manufacturing an organic light-emitting display device using the cathode deposition mask 22 may be substantially identical to the flowchart of FIG. 1. That is, the method of manufacturing an organic light-emitting display device using the cathode deposition mask 22 may include preparing a substrate including a plurality of pixel regions which respectively include anodes and organic layers disposed on the anodes and are arranged in a matrix (operation S10), performing a first deposition process using a cathode deposition mask (operation S20), and performing a second deposition process (operation S30) after moving the cathode deposition mask a distance equal to a pitch of the pixel regions along a column dimension from the position where the first deposition process (operation S20) was performed.

A substrate prepared to include the pixel regions which respectively include the anodes and the organic layers disposed on the anodes and are arranged in a matrix (operation S10) may be substantially identical to the substrate 10 of FIG. 2.

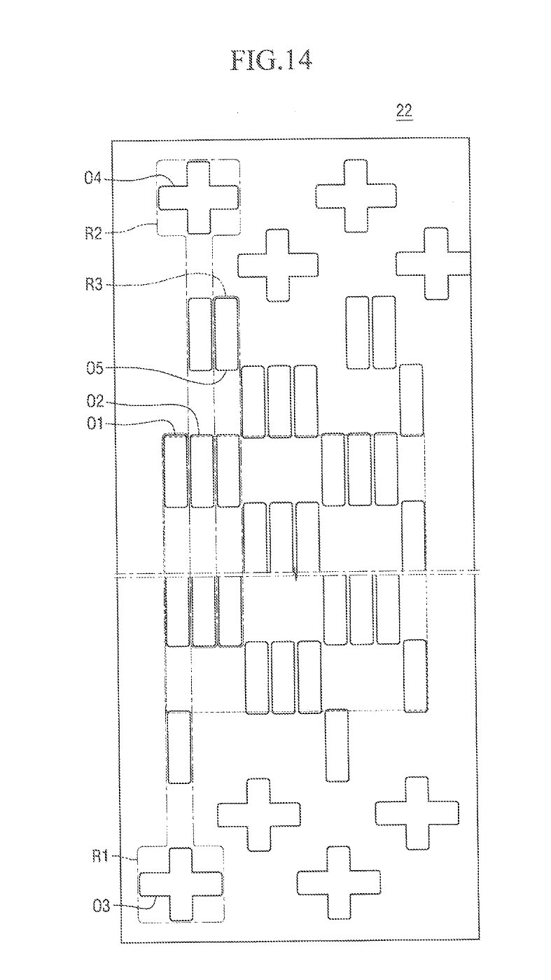

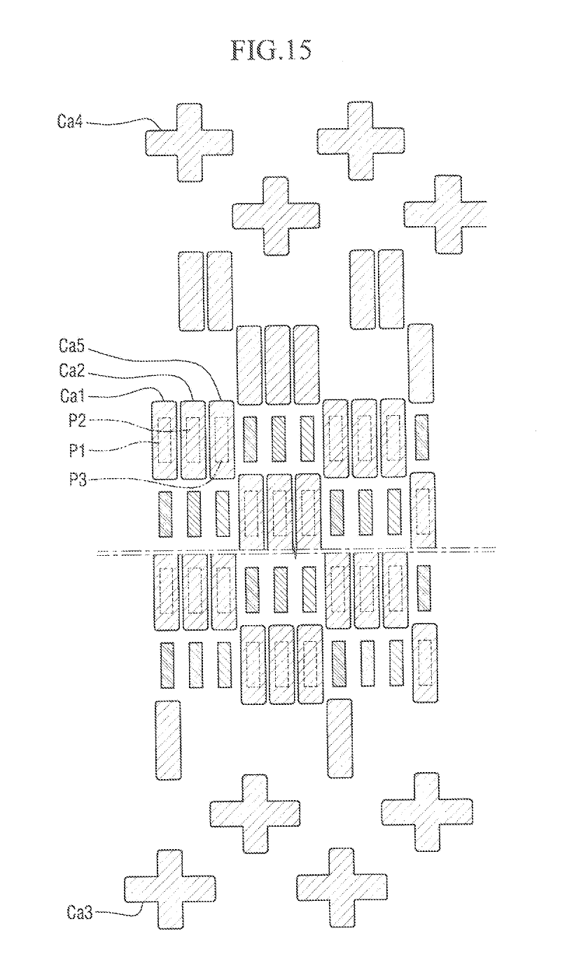

The performing of the first deposition process using the cathode deposition mask (operation S20) will now be described with reference to FIGS. 14 and 15. FIG. 14 is a plan view illustrating a state in which the cathode deposition mask 22 is placed on a substrate 10 in the first deposition process according to another embodiment of the present invention. FIG. 15 is a plan view of the substrate 10 after the first deposition process according to another embodiment of the present invention.

Referring to FIG. 14, the performing of the first deposition process using the cathode deposition mask (operation S20) includes placing the cathode deposition mask 22 on the substrate 10 as shown in FIG. 14. In the first deposition process, the first columns R1 of the cathode deposition mask may be placed on first pixel region columns PR1, the second columns R2 of the mask may be placed on second pixel region columns PR2, and the third columns R3 of the mask may be placed on third pixel region columns PR3.

In the first deposition process, first pixel regions P1 may be exposed through the first openings O1 of the cathode deposition mask 22. One first opening O1 of the cathode deposition mask 22 may expose one first pixel region P1. If one first opening O1 of the cathode deposition mask 22 exposes one first pixel region P1, the second deposition process will not deposit cathode material over the same positions of the first pixel region P1 where cathode material was deposited in the first deposition process. Deterioration of display quality of an organic light-emitting display device may be prevented when cathode materials are deposited in one operation in a uniform and homogeneous manner on each individual pixel, allowing the pixels to collectively exhibit a consistent index of refraction. At least one of a plurality of first openings O1 included in one first column R1 of the cathode deposition mask may overlay a region of the substrate that does not include first pixel region P1. The number of the first openings O1 included in one first column R1 may be greater than half the number of the first pixel regions P1 included in one first pixel region column PR1. Again, this allows for use of the cathode deposition mask on substrates prepared with varied numbers of pixel regions P1.

In the first deposition process, second pixel regions P2 may be exposed through the second openings O2 of the cathode deposition mask 22. One second opening O2 of the cathode deposition mask 22 may expose one second pixel region P2. If one second opening O2 of the cathode deposition mask 22 exposes one second pixel region P2, the second deposition process will not deposit cathode material over the same positions of the second pixel region P2 where cathode material was deposited in the first deposition process. Deterioration of display quality of the organic light-emitting display device may be prevented when cathode materials are deposited in one operation in a uniform and homogeneous manner on each individual pixel, allowing the pixels to collectively exhibit a consistent index of refraction. At least one of a plurality of second openings O2 included in one second column R2 of the cathode deposition mask may overlay a region of the substrate that does not include a second pixel region P2. The number of the second openings O2 included in one second column R2 may be greater than half the number of the second pixel regions P2 included in one second pixel region column PR2. This allows for use of the cathode deposition mask on substrates prepared with varied numbers of pixel regions P2.

In the first deposition process, third pixel regions P3 may be exposed through the fifth openings O5 of the cathode deposition mask 22. One fifth opening O5 of the cathode deposition mask 22 may expose one third pixel region P3. If one fifth opening O5 of the cathode deposition mask 22 exposes one third pixel region P3, the second deposition process will not deposit cathode material over the same positions of the third pixel region P3 where cathode material was deposited in the first deposition process. Deterioration of display quality of the organic light-emitting display device may be prevented when cathode materials are deposited in one operation in a uniform and homogeneous manner on each individual pixel, allowing the pixels to collectively exhibit a consistent index of refraction. At least one of a plurality of fifth openings O5 included in one third column R3 of the cathode deposition mask may overlay a region of the substrate that does not include a third pixel region P3. Thus, the third pixel region P3 may not be exposed by the at least one of the plurality of fifth openings O5 included in one third column R3 which overlays a region of the substrate that does not include a third pixel region P3. The number of the fifth openings O5 included in one third column R3 of the mask may be greater than half the number of the third pixel regions P3 included in one third pixel region column PR3 of the substrate. This allows for use of the cathode deposition mask on substrates prepared with varied numbers of pixel regions P3.

Referring to FIG. 15, first through fifth step S20 cathode patterns Ca1 through Ca5 may be formed on the substrate 10 by the first deposition process. The first through fifth step S20 cathode patterns Ca1 through Ca5 may be formed of substantially the same material as the first through fourth step S20 cathode patterns Ca1 through Ca4 of FIG. 8. The first through fifth step S20 cathode patterns Ca1 through Ca5 may be cathode patterns deposited on the substrate 10 through the first through fifth openings O1 through O5, respectively. Positions and shapes of the first through fifth step S20 cathode patterns Ca1 through Ca5 may be substantially identical to those of the first through fifth openings O1 through O5 shown in FIG. 14, respectively.

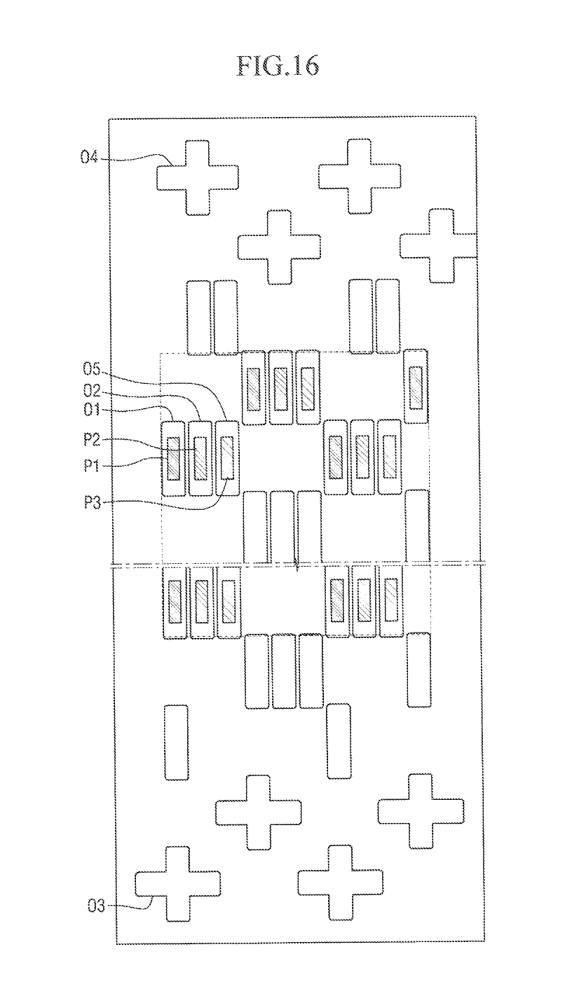

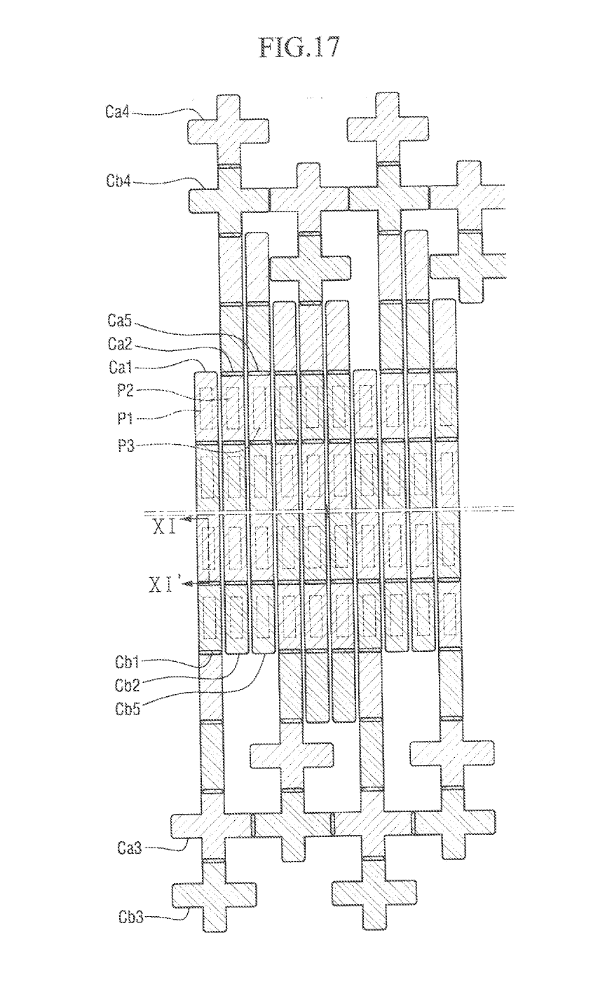

The performing of the second deposition process (operation S30) after moving the cathode deposition mask a distance equal to the pitch of the pixel regions along the column dimension from the point where the first deposition process (operation S20) was performed will now be described with reference to FIGS. 16 and 17. FIG. 16 is a plan view illustrating a state in which the cathode deposition mask 22 is placed on the substrate 10 in the second deposition process according to another embodiment of the present invention. FIG. 17 is a plan view of the substrate 10 after the second deposition process according to an embodiment of the present invention.

Referring to FIG. 16, the performing of the second deposition process using the cathode deposition mask (operation S30) includes placing the cathode deposition mask 22 on the substrate 10 as shown in FIG. 16. For the second deposition process, the cathode deposition mask 22 may be moved a distance equal to a pixel pitch PPC along the column dimension from the point where the first deposition process was performed. To be placed as shown in FIG. 16, the cathode deposition mask 22 may be moved downward in the column direction a distance equal to the pixel pitch PPC along the column dimension from the position of the cathode deposition mask 22 in FIG. 14. However, this is merely an example. According to some embodiments, the position of the cathode deposition mask 22 in the first deposition process shown in FIG. 14 and the position of the cathode deposition mask 22 in the second deposition process shown in FIG. 16 can be reversed.

In the second deposition process, the first columns R1 of the mask may be placed on the first pixel region columns PR1 of the substrate, the second columns R2 of the mask may be placed on the second pixel region columns PR2 of the substrate, and the third columns R3 of the mask may be placed on the third pixel region columns PR3 of the substrate.

In the second deposition process, the first pixel regions P1 may be exposed through the first openings O1 of the cathode deposition mask 22. One first opening O1 of the cathode deposition mask 22 may expose one first pixel region P1. If one first opening O1 of the cathode deposition mask 22 exposes one first pixel region P1, the second deposition process will not deposit cathode material over the same positions of the first pixel regions P1 where cathode material was deposited in the first deposition process. Deterioration of display quality of the organic light-emitting display device may be prevented when cathode materials are deposited in one operation in a uniform and homogeneous manner on each individual pixel, allowing the pixels to collectively exhibit a consistent index of refraction. At least one of a plurality of first openings O1 included in one first column R1 of the cathode deposition mask may overlay a region of the substrate that does not include a first pixel region P1. In the second deposition process, the second pixel regions P2 may be exposed through the second openings O2 of the cathode deposition mask 22. One second opening O2 of the cathode deposition mask 22 may expose one second pixel region P2. If one second opening O2 of the cathode deposition mask 22 exposes one second pixel region P2, the second deposition process will not deposit cathode material over the same positions of the second pixel regions P2 where cathode material was deposited in the first deposition process. Deterioration of display quality of the organic light-emitting display device may be prevented when cathode materials are deposited in one operation in a uniform and homogeneous manner on each individual pixel, allowing the pixels to collectively exhibit a consistent index of refraction. At least one of a plurality of second openings O2 included in one second column R2 of the cathode deposition mask may overlay a region of the substrate that does not include a second pixel region P2.

In the second deposition process, the third pixel regions P3 may be exposed through the fifth openings O5 of the cathode deposition mask 22. One fifth opening O5 of the cathode deposition mask 22 may expose one third pixel region P3. If one fifth opening O5 of the cathode deposition mask 22 exposes one third pixel region P3, the second deposition process will not deposit cathode material over the same positions of the third pixel regions P3 where cathode material was deposited in the first deposition process. Deterioration of display quality of the organic light-emitting display device may be prevented when cathode materials are deposited in one operation in a uniform and homogeneous manner on each individual pixel, allowing the pixels to collectively exhibit a consistent index of refraction. At least one of a plurality of fifth openings O5 included in one third column R3 of the cathode deposition mask may overlay a region of the substrate that does not include a third pixel region P3. Referring to FIG. 17, first through fifth step S30 cathode patterns Cb1 through Cb5 may be formed on the substrate 10 by the second deposition process. The first through fifth step S30 cathode patterns Cb1 through Cb5 may be formed of substantially the same material as the first through fifth step S20 cathode patterns Ca1 through Ca5. The first through fifth step S30 cathode patterns Cb1 through Cb5 may be cathode patterns deposited on the substrate 10 through the first through fifth openings O1 through O5, respectively.

Each of the first step S30 cathode patterns Cb1 may be formed to partially overlap a first step S20 cathode pattern Ca1 or a third step S20 cathode pattern Ca3 which is adjacent to the first step S30 cathode pattern Cb1 along the column dimension. Each of the third step S30 cathode patterns Cb3 may be formed to overlap third step S20 cathode patterns Ca3, in particular, a third step S20 cathode pattern Ca3 which is adjacent to the third step S30 cathode pattern Cb3 along the column dimension and a third step S20 cathode pattern Ca3 which is adjacent to the third step S30 cathode pattern Cb3 along the row dimension. Therefore, the first step S20 cathode patterns Ca1, the third step S20 cathode patterns Ca3, the first step S30 cathode patterns Cb1, and the third step S30 cathode patterns Cb3 disposed on the substrate 10 may all be connected to form a first cathode. The first cathode may be disposed on the first pixel regions P1.

Each of the second step S30 cathode patterns Cb2 may be formed to partially overlap a second step S20 cathode pattern Ca2 or a fourth step S20 cathode pattern Ca4 which is adjacent to the second step S30 cathode pattern Cb2 along the column dimension. Each of the fourth step S30 cathode patterns Cb4 may be formed to overlap a second step S20 cathode pattern Ca2 or a fourth step S20 cathode pattern Ca4 which is adjacent to the fourth step S30 cathode pattern Cb4 in the column direction and a fourth step S20 cathode pattern Ca4 which is adjacent to the fourth step S30 cathode pattern Cb4 along the row dimension. In this way, the second step S20 cathode patterns Ca2, the fourth step S20 cathode patterns Ca4, the second step S30 cathode patterns Cb2, and the fourth step S30 cathode patterns Cb4 disposed on the substrate 10 may all be connected to form a second cathode. The second cathode may be disposed on the second pixel regions P2. The second cathode may be separated from the first cathode.

Each of the fifth step S30 cathode patterns Cb5 may be formed to partially overlap a fifth step S20 cathode pattern Ca5 which is adjacent to the fifth step S30 cathode pattern Cb5 along the column dimension. Therefore, a plurality of cathode pattern lines, each including a plurality of fifth step S20 cathode patterns Ca5 and a plurality of fifth step S30 cathode patterns Cb3 connected to the fifth step S20 cathode patterns Ca5, may be formed on the substrate 10. The cathode pattern lines may be separated from each other. Although not shown in the drawing, the separate cathode pattern lines, each including the fifth step S20 cathode patterns Ca5 and the fifth step S30 cathode patterns Cb3 connected to the fifth step S20 cathode patterns Ca5, may be connected to each other on a layer different from a layer on which the first and second cathodes have been formed, thereby forming a third cathode. The third cathode may be separated from the first cathode and the second cathode.

As described above, according to an embodiment of the present invention, an organic light-emitting display device including first, second and third cathodes which are separated from each other may be formed using one cathode deposition mask 22 without island patterns. An examination of FIG. 17 shows the island patterns that would be required to form a comparable organic light-emitting display device using a single mask with a single deposition process. In practice in the conventional art, the illustrated device might be formed using a plurality of masks. By means of the present invention, the number of masks needed to deposit cathodes may be reduced in comparison, thereby simplifying the manufacturing process. In addition, since different voltages may be applied to the cathodes according to the colors of the corresponding pixels, power consumption of the organic light-emitting display device may be reduced.

Embodiments of the present invention provide at least one of the following advantages.

That is, a cathode deposition mask which does not have island patterns, such as those suggested by FIGS. 10 and 17, and can be used to form a cathode divided into a plurality of regions may be provided.

In addition, efficiency of the process of manufacturing an organic light-emitting display device may be improved.

However, the present invention is not restricted to the embodiments set forth herein. The above and other effects of the present invention will become more apparent to a person of ordinary skill in the art to which the present invention pertains by referencing the claims appended below.

What is claimed is:

1. A cathode deposition mask comprising:
a plurality of first columns and a plurality of second columns arranged alternately,
the plurality of first columns and the plurality of second columns being parallel to each other and defining a column dimension along the length of each column,
the first columns and the second columns each comprising a plurality of openings,
the plurality of openings included in each first column being arranged alternately along the column dimension with respect to the openings in each adjacent first column, and
the plurality of openings included in each second column being arranged alternately along the column dimension with respect to the openings in each adjacent second column.

2. The cathode deposition mask of claim 1, the mask having a single row dimension that is perpendicular to the column dimension, the openings included in the first columns and the second columns comprising first through fourth openings, each of the first columns comprising a plurality of first openings and a third opening, and each of the second columns comprising a plurality of second openings and a fourth opening, a length of the third opening along the row dimension being greater than a pitch of the first columns along the row dimension, and a length of the fourth opening along the row dimension being greater than a pitch of the second columns along the row dimension.

3. The cathode deposition mask of claim 2, a length of the first openings in each first column along the column dimension being greater than a distance between two first openings which are adjacent to each other along the column dimension, and a length of the second openings in each second column along the column dimension being greater than a distance between two second openings which are adjacent to each other along the column dimension.

4. The cathode deposition mask of claim 2, the portions of the column dimension being occupied by the first openings included in each of the first columns overlapping the portions of the column dimension occupied by the first openings that are adjacent along the column dimension and are included in adjacent first columns, and the portions of the column dimension being occupied by the second openings included in each of the second columns overlapping the portions of the column dimension occupied by the second openings that are adjacent along the column dimension and are included in adjacent second columns.

5. The cathode deposition mask of claim 2, each first column and each second column having a first end and a second end, the first end of each first column being adjacent to the first end of each adjacent second column, the second end of each second column being adjacent to the second end of each adjacent first column, one of the third openings being disposed adjacent to a first end of each of the first columns, and one of the fourth openings being disposed adjacent to a second end of each of the second columns.

6. The cathode deposition mask of claim 5, a length of each first opening along the column dimension and a length of each third opening along the column dimension each being greater than a distance between the third opening and a first opening which is in the same first column and adjacent to the third opening along the column dimension, and a length of each second opening along the column dimension and a length of each fourth opening along the column dimension each being greater than a distance between the fourth opening and a second opening which is in the same second column and adjacent to the fourth opening along the column dimension.

7. The cathode deposition mask of claim 5, the third opening comprising a first region having a length along the column dimension which is longer than its width along the row dimension and a second region having a length along the row dimension which is longer than its width along the column dimension, and the fourth opening comprising a third region having a length along the column dimension which is longer than its width along the row direction and a fourth region having a length along the row dimension which is longer than its width along the column dimension.

8. The cathode deposition mask of claim 7, the width of the second region of the third opening being smaller than the distance between the third opening and the first opening which is adjacent to the third opening along the column dimension, and the width of the fourth region of the fourth opening being smaller than the distance between the fourth opening and the second opening which is adjacent to the fourth opening along the column dimension.

9. The cathode deposition mask of claim 7, the width of the first region of each third opening being equal to or less than a length of the first openings along the row dimension, and the width of the third region of the fourth opening being equal to or less than a length of the second openings along the row dimension.

10. A cathode deposition mask comprising:
a plurality of first columns, a plurality of second columns and a plurality of third columns arranged alternately,
the plurality of first columns, the plurality of second columns and the plurality of third columns being parallel to each other and defining a column dimension along the length of each column,
the first columns, the second columns and the third columns each comprising a plurality of openings,
the plurality of openings included in each first column being arranged alternately along the column dimension with respect to the openings in each adjacent first column,
the plurality of openings included in each second column being arranged alternately along the column dimension with respect to the openings in each adjacent second column, and
the plurality of openings included in each third column being arranged alternately along the column dimension with respect to the openings in each adjacent third column.

11. The cathode deposition mask of claim 10, the openings included in the first columns, the second columns and the third columns comprising first through fifth openings, each of the first columns comprising a plurality of first openings and a third opening, each of the second columns comprising a plurality of second openings and a fourth opening, and each of the third columns comprising a plurality of fifth openings.

12. The cathode deposition mask of claim 11, a length of the first openings in each first column along the column dimension being greater than a distance between two first openings which are adjacent to each other along the column dimension, a length of the second openings in each second column along the column dimension being greater than a distance between two second openings which are adjacent to each other along the column dimension, and a length of the fifth openings in each third column along the column dimension being greater than a distance between two fifth openings which are adjacent to each other along the column dimension.

13. The cathode deposition mask of claim 11, the mask having a single row dimension that is perpendicular to the column dimension, a length of the third opening along the row dimension being greater than a pitch of the first columns along the row dimension, and a length of the fourth opening along the row dimension being greater than a pitch of the second columns along the row dimension.

14. The cathode deposition mask of claim 11, the first columns, the second columns and the third columns each having a first end and a second end, each first end being adjacent to all other first ends and each second end being adjacent to all other second ends, the third opening being disposed adjacent to a first end of each of the first columns, and the fourth opening being disposed adjacent to a second end of each of the second columns.

15. A method of manufacturing an organic light-emitting display device, the method comprising:
preparing a substrate comprising a plurality of pixel regions which respectively comprise anodes and organic layers disposed on the anodes, the pixel regions being arranged in a matrix comprising a series of parallel columns and a series of parallel rows, the axes of the columns defining a matrix column dimension;
performing a first process of depositing a conductive material using a cathode deposition mask; and
performing a second process of depositing the conductive material after moving the cathode deposition mask along the matrix column dimension over a distance equal to a pitch of the pixel regions along the matrix column dimension,
the cathode deposition mask comprising a plurality of first columns and a plurality of second columns arranged alternately, the plurality of first columns and the plurality of second columns being parallel to each other and defining a mask column dimension along the length of each column,
a plurality of openings included in each first column being arranged alternately along the mask column dimension with respect to the openings in each adjacent first column, and
a plurality of openings included in each second column being arranged alternately along the mask column dimension with respect to the openings in each adjacent second column.

16. The method of claim 15, the pixel regions comprising:
a plurality of first pixel region columns, each comprising a plurality of first pixel regions;
a plurality of second pixel region columns, each comprising a plurality of second pixel regions; and
a plurality of third pixel region columns, each comprising a plurality of third pixel regions,
the first through third pixel region columns being arranged alternately, and, in the first deposition process, the first columns of the mask being placed on the first pixel region columns of the matrix, and the second columns of the mask being placed on the second and third pixel region columns of the matrix.

17. The method of claim 16, the openings of the first column and the second column comprising first through fourth openings, each of the first columns comprising a plurality of first openings and a third opening, and each of the second columns comprising a plurality of second openings and a fourth opening, one first opening of the cathode deposition mask exposing in the first performing step one first pixel region, and one second opening of the cathode deposition mask exposing in the first performing step one second pixel region and one third pixel region.

18. A method of manufacturing an organic light-emitting display device, the method comprising:
preparing a substrate comprising a plurality of pixel regions which respectively comprise anodes and organic layers disposed on the anodes, the pixel regions being arranged in a matrix comprising a series of parallel columns and a series of parallel rows, the axes of the columns defining a matrix column dimension;
performing a first process of depositing a conductive material using a cathode deposition mask; and
performing a second process of depositing the conductive material after moving the cathode deposition mask along the matrix column dimension over a distance equal to a pitch of the pixel regions along the matrix column dimension,
the cathode deposition mask comprising a plurality of first columns, a plurality of second columns and a plurality of third columns arranged alternately, the plurality of first columns and the plurality of second columns being parallel to each other and defining a mask column dimension along the length of each column,
a plurality of openings included in each first column being arranged alternately along the mask column dimension with respect to the openings in each adjacent first column,
a plurality of openings included in each second column being arranged alternately along the mask column dimension with respect to the openings in each adjacent second column, and
a plurality of openings included in each third column being arranged alternately along the mask column dimension with respect to the openings in each adjacent third column.

19. The method of claim 18, the pixel regions comprising:
a plurality of first pixel region columns, each comprising a plurality of first pixel regions;
a plurality of second pixel region columns, each comprising a plurality of second pixel regions; and
a plurality of third pixel region columns, each comprising a plurality of third pixel regions,
the first through third pixel region columns being arranged alternately, and, in the first performing step, the first columns of the mask being placed on the first pixel region columns, the second columns of the mask being placed on the second pixel region columns, and the third columns of the mask being placed on the third pixel region columns.

20. The method of claim 19, the openings in the first column, the second column and the third column comprising first through fifth openings, each of the first columns comprising a plurality of first openings and a third opening, each of the second columns comprising a plurality of second openings and a fourth opening, and each of the third columns comprising a plurality of fifth openings, one first opening of the cathode deposition mask exposing in each of the first and second performing steps one first pixel region, one second opening of the cathode deposition mask exposing in each of the first and second performing steps one second pixel region, and one fifth opening of the cathode deposition mask exposing in each of the first and second performing steps one third pixel region.
